(19) United States
(12) Patent Application Publication
(10) Pub. No.: US 2013/0100005 A1
(43) Pub. Date: Apr. 25, 2013

(54) LCD Panel and Method of Manufacturing the Same

(71) Applicants: Ming Hung Shih, Guangdong (CN); Haiying He, Guangdong (CN)

(72) Inventors: Ming Hung Shih, Guangdong (CN); Haiying He, Guangdong (CN)

(73) Assignee: SHENZHEN CHINA STAR OPTOELECTRONICS TECHNOLOGY CO., LTD., Shenzhen (CN)

(21) Appl. No.: 13/376,589

(22) PCT Filed: Oct. 21, 2011
(86) PCT No.: PCT/CN2011/081093

§ 371 Date: Dec. 6, 2011

(30) Foreign Application Priority Data
Oct. 19, 2011 (CN) 201110318252.5

(51) Int. Cl. G09G 3/36; H01L 33/08

(52) U.S. Cl. 345/92; 438/34; 257/E33.053

(57) ABSTRACT

A liquid crystal display panel and its manufacturing method are proposed. The liquid crystal display includes pixels, scan lines, and data lines. The scan lines are formed by a first metallic layer. Each pixel includes multiple subpixels. Each subpixel includes a pixel electrode, a thin-film transistor, and a common electrode line. The common electrode line includes a main branch, a first shielding metallic area, and a second shielding metallic area. The first and second shielding metallic areas are parallel to the scan lines and are connected to the main branch. The data lines and the common electrode lines are formed by the second metallic layer. The scan line and the common electrode line are formed after the first and second metallic layers undergo different etching processes, causing the distance between the scan line and the common electrode line to be shortened and the width of the common electrode line serving as a shielding metallic area partially to be properly decreased. Accordingly, the pixel aperture ratio is increased.

### BACKGROUND OF THE INVENTION

1. Field of the Invention

The present invention relates to a liquid crystal display (LCD) panel, and more particularly, to an LCD panel comprising tri-gate pixels having a high aperture ratio.

2. Description of the Prior Art

A thin flat display is widely used in current consumer electronic products. Liquid crystal displays (LCDs) which are colorful monitors with high resolution are widely used in various electronic products such as monitors for mobile phones, personal digital assistants (PDAs), digital cameras, laptop computers, and notebook computers.

The pixel structure of the TFT-LCD device may generally be categorized into two types; single-gate pixel structure and tri-gate pixel structure. When displaying images with the resolution of n×m pixels, the TFT-LCD device having the tri-gate pixel structure includes 3×m gate lines and n data lines, whereas the TFT-LCD device having a single-gate pixel structure comprises m gate lines and 3×n data lines. In other words, under identical resolution, the number of gate lines of the TFT-LCD device having the tri-gate pixel structure is triple to that of the TFT-LCD device having the single-gate pixel structure; however the number of scan lines of the TFT-LCD device having the tri-gate pixel structure is only one-third of that of the TFT-LCD device having the single-gate pixel structure. Therefore the conventional TFT-LCD device having the tri-gate pixel structure, compare to the single-gate pixel structure, employs more gate drivers but less source drivers. Since the cost and power consumption of the gate driver is less than that of the source driver, utilizing the TFT-LCD device having the tri-gate pixel structure is more advantageous due to the relatively low cost and low power consumption.

Referring to FIG. 1, FIG. 1 shows a top view of a subpixel of a tri-gate pixel in a conventional LCD panel. The LCD panel comprises a plurality of pixels. Each pixel comprises at least three subpixels 100, (i.e., red subpixel, green subpixel, and blue subpixel). Each of the subpixels 100 comprises a thin-film transistor (TFT) 102 and a pixel electrode 112. The TFT 102 has a gate electrically connected to a scan line 104, a source electrically connected to a data line 106, and a drain electrically connected to the pixel electrode 112. The pixel electrode 112 covers a common electrode line 108 and shielding metallic areas 110. To facilitate the description, FIG. 1 illustrates a relative position of the pixel electrode 112. The common electrode line 108 is used for supplying common voltage. An overlap of the common electrode line 108 and the pixel electrode 112 forms a storage capacitor. When a scan signal is transmitted to the TFT 102 through the scan line 104, the TFT 102 will be turned on. Then, a data signal from the data line 106 passes the turn-on TFT 102 and is transmitted to the pixel electrode 112. Finally, the pixel electrode 112 obtains its required voltage at full charge. The alignment of LC molecules under the pixel electrode 112 is controlled depending on the voltage difference between the data signal applied on the pixel electrode 112 and the common voltage, causing the subpixel 100 to show different degrees of brightness. The alignment of the LC molecules will not change because of the voltage difference between the common voltage and the data signal applied on the pixel electrode 112 stored by the storage capacitor until the TFT 102 receives a succeeding scan signal. The shielding metallic areas 110 disposed at both sides of the scan line 104 are used for increasing the capacitance of the storage capacitor and reducing parasitic capacitance. The shielding metallic areas 110 are electrically connected to the common electrode line 108 via a via 114, causing the shielding metallic areas 110 and the common electrode line 108 to be at the same electrical potential. Thus, the data signal in the pixel electrode 112 can be prevented from being affected by the parasitic capacitance.

In the conventional technology, the gate of the TFT 102, the shielding metallic areas 110, and the scan line 104 all are formed by a first metallic layer, while the source and drain of the TFT 102, the data line 106, and the common electrode line 108 all are formed by a second metallic layer. The TFT 102, the shielding metallic areas 110, the scan line 104, the data line 106, and the common electrode line 108 are defined as the opaque area of the subpixel 100. The aperture ratio of the subpixel 100 is defined as the ratio of a light-permeable area to the total subpixel 100 (including the opaque area). The subpixel 100 aperture ratio directly affects the utilization of backlight sources and the brightness of the LCD panel. The large subpixel 100 aperture ratio provides the LCD panel with a high brightness and a high contrast ratio, and vice versa. In other words, in order to increase the subpixel 100 aperture ratio, the opaque area has to be decreased as more as possible and the total pixel area has to be minimalized. The smaller the TFT 102 (or the thinner the scan line 104 and the data line 106) is, the higher the subpixel 100 aperture ratio is.

However, the width W1 of the scan line 104 is generally larger than the width W2 of the data line 106 due to the restriction of manufacturing processes. Also, a specific distance d1 needs to be spared between each of the shielding metallic areas 110 and the scan line 104 since the shielding metallic area 110 and the scan line 104 are formed by the same metallic layer. The two reasons cause the aperture ratio to be lowered.

Although the LCD panel having the tri-gate pixels has advantages of low cost and low power consumption, the low pixel aperture ratio has room to be improved.

### SUMMARY OF THE INVENTION

Therefore, an object of the present invention is to provide an LCD panel having a high pixel aperture ratio for solving problems occurring in the conventional technology.

The present invention proposes a liquid crystal display (LCD) panel, comprising a plurality of pixels, a plurality of rows of scan lines parallel to one another and arranged along a first direction, and a plurality of columns of data lines parallel to one another and arranged along a second direction. The second direction is perpendicular to the first direction. The plurality of rows of scan lines are formed by a first metallic layer for transmitting scan signals. The plurality of columns of data lines are formed by a second metallic layer for transmitting data signals. Each of the plurality of pixels comprises a plurality of subpixels. Each of the plurality of subpixels comprises: a pixel electrode, formed by a transparent conducting layer; a thin-film transistor (TFT), connected to the pixel electrode, the scan line, and the data line; and a common electrode line, comprising a main branch, a first shielding metallic area, and a second shielding metallic area, the first and second shielding metallic areas being parallel to the plurality of scan lines and being connected to the main branch, and the common electrode line formed by the second metallic layer. An insulating layer is disposed between the first and second metallic layers. Two vias are defined on the insulating layer, and the transparent conducting layer is positioned on the two vias and on the first metallic layer, so that two main branches of common electrode lines corresponding to two subpixels which are on two sides of one of the data lines and are connected to one of the scan lines are electrically connected to each other through the transparent conducting layer and the first metallic layer.

The present invention also proposes a liquid crystal display (LCD) panel, comprising a plurality of pixels, a plurality of rows of scan lines parallel to one another and arranged along a first direction, and a plurality of columns of data lines parallel to one another and arranged along a second direction. The second direction is perpendicular to the first direction. The plurality of rows of scan lines are formed by a first metallic layer for transmitting scan signals. The plurality of columns of data lines are formed by a second metallic layer for transmitting data signals. Each of the plurality of pixels comprises a plurality of subpixels. Each of the plurality of subpixels comprises: a pixel electrode, formed by a transparent conducting layer; a thin-film transistor (TFT), connected to the pixel electrode, the scan line, and the data line; and a common electrode line, comprising a main branch, a first shielding metallic area, and a second shielding metallic area, the first and second shielding metallic areas being parallel to the plurality of scan lines and being connected to the main branch, and the common electrode line formed by the second metallic layer.

According to present invention, the main branch of the common electrode line appears cruciform.

According to present invention, the LCD panel further comprises an insulating layer disposed between the first and second metallic layers.

According to present invention, two common electrode lines which correspond to two of the plurality of subpixels, are disposed at two sides of one of the data lines, and are connected to one of the scan lines are electrically connected to each other.

According to present invention, the LCD panel further comprises two vias penetrating the insulating layer, and the transparent conducting layer is positioned on the two vias and on the first metallic layer, causing the two common electrode lines to be electrically connected to each other through the transparent conducting layer and the first metallic layer.

According to present invention, the first shielding metallic area of one of the two common electrode lines is electrically connected to the first shielding metallic area of the other, or the second shielding metallic area of one of the two common electrode lines is electrically connected to the second shielding metallic area of the other through the transparent conducting layer and the first metallic layer.

According to present invention, each pixel comprises a red subpixel, a green subpixel, and a blue subpixel.

According to present invention, the transparent conducting layer is made of indium tin oxide.

The present invention also proposes a method of manufacturing an LCD panel. The method comprises:

providing a glass substrate;

forming a first metallic layer on the glass substrate;

etching the first metallic layer for forming a gate of a TFT and a scan line;

forming an insulating layer on a gate of the TFT and on the scan line;

forming a passage of the TFT on the insulating layer; and

forming and etching a second metallic layer for forming a source and a drain of the TFT, a common electrode line, and a data line wherein the common electrode line comprises a main branch, a first shielding metallic area, and a second shielding metallic area, and the first and second shielding metallic areas are parallel to the scan line and are connected to the main branch.

According to present invention, the method further comprises:

forming a passivation layer on the data line, the common electrode line, and on the source and drain of the TFT;

etching a via on the passivation layer under the common electrode line; and forming a transparent conducting layer on the via and on the first metallic layer, causing the common electrode line to be electrically connected to the first metallic layer through the transparent conducting layer.

According to present invention, the method further comprises:

etching the passivation layer on the drain for forming a hole while etching the passivation layer under the common electrode line for forming the via; and

forming the transparent conducting layer on the hole for producing a pixel electrode while forming the transparent conducting layer on the via and on the first metallic layer.

In contrast to the conventional technology, the present invention provides an LCD panel and a method of manufacturing the same. The LCD panel has a scan line formed by a first metallic layer and a data line and a common electrode line formed by a second metallic layer. The scan line and the common electrode line are formed after the first and second metallic layers undergo different etching processes, causing the distance between the scan line and the common electrode line to be shortened and the width of the common electrode line serving as a shielding metallic area partially to be properly decreased. Accordingly, the pixel aperture ratio is increased.

These and other features, aspects and advantages of the present disclosure will become understood with reference to the following description, appended claims and accompanying figures.

### BRIEF DESCRIPTION OF THE DRAWINGS

FIG. 1 shows a top view of a subpixel of a tri-gate pixel in a conventional LCD panel.

FIG. 2 shows a schematic diagram of an LCD having tri-gate pixels according to a preferred embodiment of the present invention.

FIG. 3 shows a circuit diagram of one of the tri-gate pixels.

FIG. 4 shows a top view of the subpixels in the LCD panel according to the first embodiment of the present invention.

FIG. 5 shows a schematic diagram of subpixels in an LCD panel according to a second embodiment of the present invention.

FIGS. 6 to 10 show schematic diagrams of manufacturing processes of the LCD panel of the present invention.

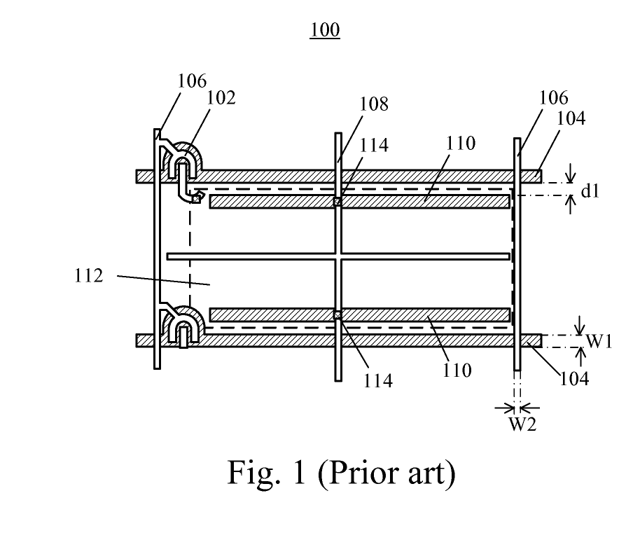

### DETAILED DESCRIPTION OF THE PREFERRED EMBODIMENTS

Certain terms are used throughout the description and following claims to refer to particular components. As one skilled in the art will appreciate, electronic equipment manufacturers may refer to a component by different names. This documents does not intend to distinguish between components that differ in name but not function. In the following description and in the claims, the terms “include” and “comprise” are used in an open-ended fashion, and thus should be interpreted to mean “include, but not limited to . . . . ” Also, the term “electrically connect” is intended to mean either an indirect or direct electrical connection. Accordingly, if one device is coupled to another device, that connection may be through a direct electrical connection, or through an indirect electrical connection via other devices and connections.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

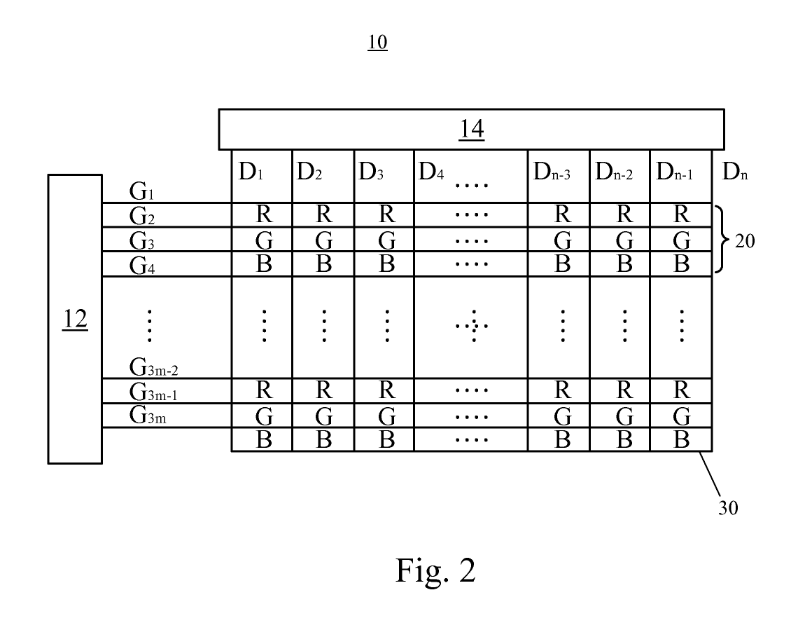

Referring to FIG. 2, FIG. 2 shows a schematic diagram of an LCD 10 having tri-gate pixels according to a preferred embodiment of the present invention. The LCD 10 comprises a gate driving module 12, a source driving module 14, and an LCD panel 30. Taking a resolution of nxm for example, the LCD panel 30 having tri-gate pixels comprises n×m tri-gate pixels 20, m×3 scan lines G₁, G₂, . . . G₃ₘ, n data lines D₁, D₂, Dₙ, and 3×m×n subpixels R, G, B defined by the scan line and the data line together. The scan lines G₁, G₂, . . . G₃ₘ are electrically connected to the gate driving module 12, and the data lines D₁, D₂, . . . Dₙ are electrically connected to the source driving module 14. Each of the tri-gate pixels 20 comprises three subpixels R, G, B.

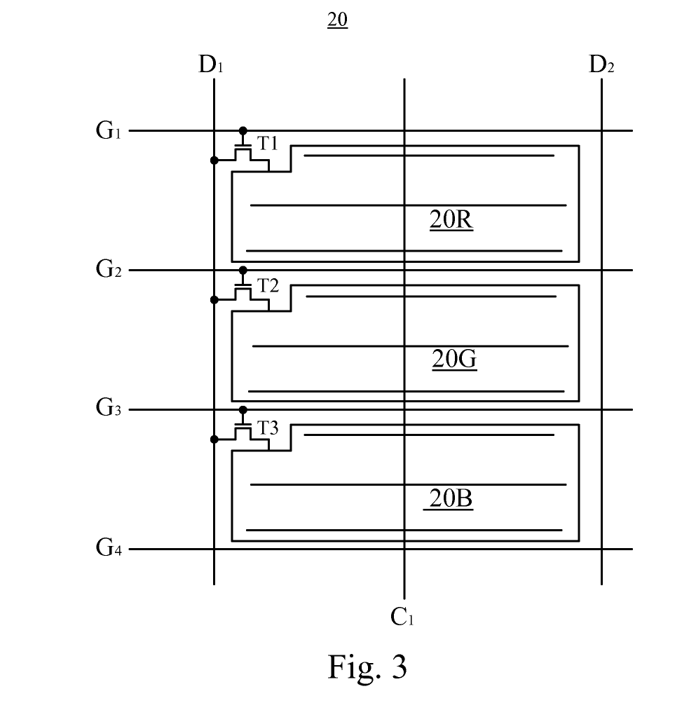

Referring to FIG. 3, FIG. 3 shows a circuit diagram of one of the tri-gate pixels 20. The tri-gate pixel 20 comprises the three subpixels (i.e., red subpixel 20R, green subpixel 20G, and blue subpixel 20B), three TFTs T1, T2, and T3 respectively disposed in the red subpixel 20R, the green subpixel 20G, and the blue subpixel 20B, and three pixel electrodes 22A, 22B, and 22C respectively disposed in the red subpixel 20R, the green subpixel 20G, and the blue subpixel 20B. The TFTs T1, T2, and T3 each has a gate electrically connected to the corresponding scan lines G₁, G₂, and G₃, respectively, a source electrically connected to the data line D₁, and a drain electrically connected to the pixel electrodes 22A, 22B, and 22C, respectively. According to this arrangement, the red subpixel 20R, the green subpixel 20G, and the blue subpixel 20B are controlled by the scan lines G₁, G₂, and G₃, respectively. Also, the red subpixel 20R, the green subpixel 206 and the blue subpixel 20B receive data signals transmitted through the data line D₁ during different periods and show different grayscales. In addition, the scan lines G₁, G₂, and G₃ are arranged along a first direction, and the data line D₁ is arranged along a second direction. The first direction is perpendicular to the second direction. A common electrode line C₁ crosses and partially overlaps the scan lines G₁, G₂, and G₃. The common electrode line C₁ partially overlaps the pixel electrodes 22A, 22B, and 22C. The overlapping areas form three storage capacitors.

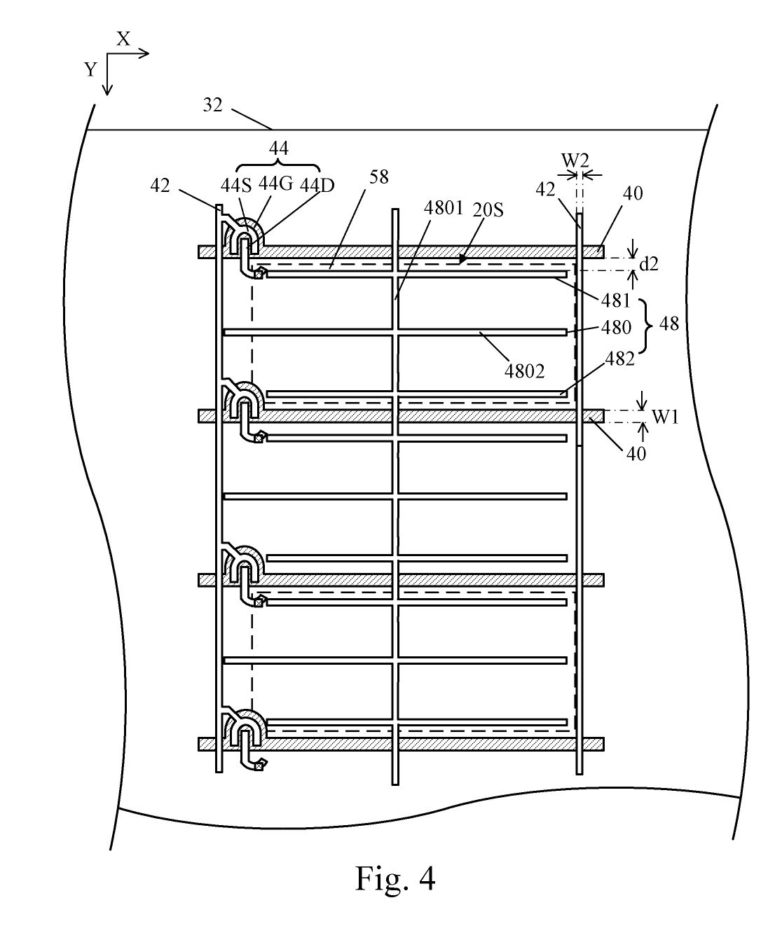

Referring to FIG. 4, FIG. 4 shows a top view of the subpixels 20S in the LCD panel according to the first embodiment of the present invention. The LCD panel 30 having the tri-gate pixels 20 is exemplified for introduction in the following embodiments though the tri-gates 20 of the present invention are not limited accordingly. As shown in FIG. 4, the LCD panel 30 comprises a glass substrate (also called TFT substrate) 32 and a plurality of tri-gate pixels 20 disposed on the glass substrate 32. Each of the plurality of tri-gate pixels 20 comprises the three subpixels 20S, that is, red subpixel, green subpixel, and blue subpixel. To facilitate the description, FIG. 4 illustrates a relative position of a pixel electrode 58. Each of the subpixels 20S is shaped as a rectangular. The longer side of each of the subpixels 20S is arranged along the first direction X, and the shorter side is arranged along the second direction Y. The first direction X is roughly perpendicular to the second direction Y. A scan line 40 formed by the first metallic layer is positioned on the glass substrate 32 along the first direction X. A data line 42 is positioned on the glass substrate 32 along the second direction Y A TFT 44 disposed in each of the subpixels 20S comprises a gate 44G, a source 44S, and a drain 44D. The gate 44G is electrically connected to its corresponding scan line 40. The source 44S is electrically connected to the data line 42. The drain 44D is electrically connected to the pixel electrode 58 disposed in each of the subpixels 20S.

A common electrode line 48 positioned on the glass substrate 32 crosses and partially overlaps the scan line 40. A storage capacitor is formed by the overlapping area of the common electrode line 48 and the pixel electrode 58. The common electrode line 48 and the scan line 40 are formed on two different metallic layers. An insulating layer (not shown) is disposed between the two metallic layers for preventing the metallic layers from being electrically connected directly. So the common electrode line 48 and the scan line 40 can be placed in different directions. The common electrode line 48 can also cross the scan line 40. For example, the scan line 40 extends along the longer side (the first direction) of the subpixels 20S, and the common electrode line 48 extends along the shorter side (the second direction) and penetrates the subpixels 20S. Thus, the area that the common electrode line 48 occupies in the display zone is reduced, causing the shielding area to be reduced, increasing the pixel aperture ratio. The common electrode line 48 and the data line 42 can be formed by the same conducting pattern such as the second metallic layer, or the common electrode line 48 can be formed by another conducting layer in this embodiment.

The common electrode line 48 comprises a main branch 480, a first shielding metallic area 481, and a second shielding metallic area 482. The first and second shielding metallic areas 481 and 482 are parallel to a plurality of rows of scan lines 40 and are connected to the main branch 480. A plurality of columns of data lines 42 and the common electrode line 48 are formed by the second metallic layer. The main branch 480 appears cruciform and is subdivided into first and second extensions 4801 and 4802. The first extension 4801 is perpendicular to the second extension 4802. The second extension 4802 crosses the first and second shielding metallic areas 481 and 482 vertically. The second extension 4802 disposed along the second direction passes through the subpixels 20S in the same column so that the common electrode lines 48 in the same column are electrically connected.

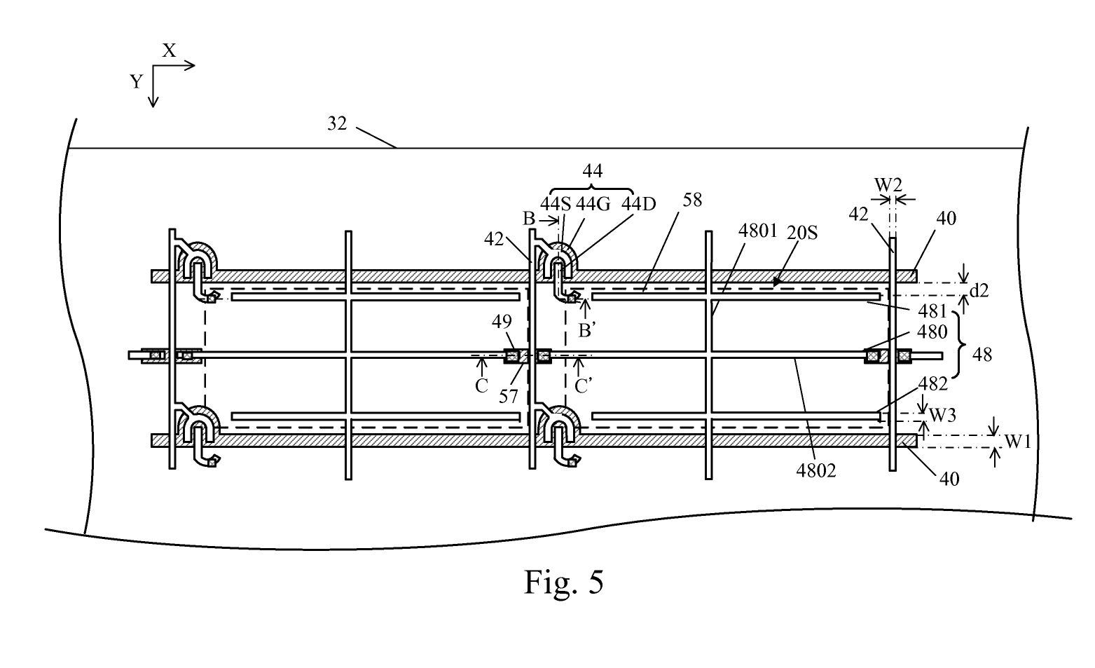

Referring to FIG. 5 and FIG. 9, FIG. 5 shows a schematic diagram of subpixels in an LCD panel according to a second embodiment of the present invention, and FIG. 9 shows a cross section view of the pixel taken along two lines B-B′ and C-C′ of FIG. 5. A via 49 is formed on the insulating layer (not shown) at the end of the first extension 4801 in this embodiment. A conducting layer such as indium tin oxide (ITO) is formed on the via 49 causing the common electrode line 48 to be electrically connected to a connecting zone 57 which is also formed by the first metallic layer. The two common electrode lines 48 which correspond to two of the subpixels 20S, are disposed at two sides of the same data line, and are connected to the scan line 40 are electrically connected to each other. In another embodiment, the via 49 can be also formed on the insulating layer at the end of the first or second shielding metallic area 481 or 482 of the two common electrode lines 48 of the subpixels 20S in the same row. Subsequently, the transparent conducting layer is formed on the via 49. The two common electrode lines 48 are electrically connected to each other through the connecting zone 57 under the via 49 and the transparent conducting layer on the via 49.

In sum, the scan line 40 on the LCD panel is formed by the first metallic layer, and the data line 42 and the common electrode line 48 are formed by the second metallic layer. For the LCD panel having the tri-gate pixels, since the scan line 40 and the common electrode line 48 are formed when different metallic layers undergo different etching processes, the distance d2 between the scan line 40 and the common electrode line 48 can be shortened. Moreover, the width W3 of the common electrode line 48 which partially serves as the first and second shielding metallic areas 481 and 482 can be properly decreased. So the pixel aperture ratio can be increased.

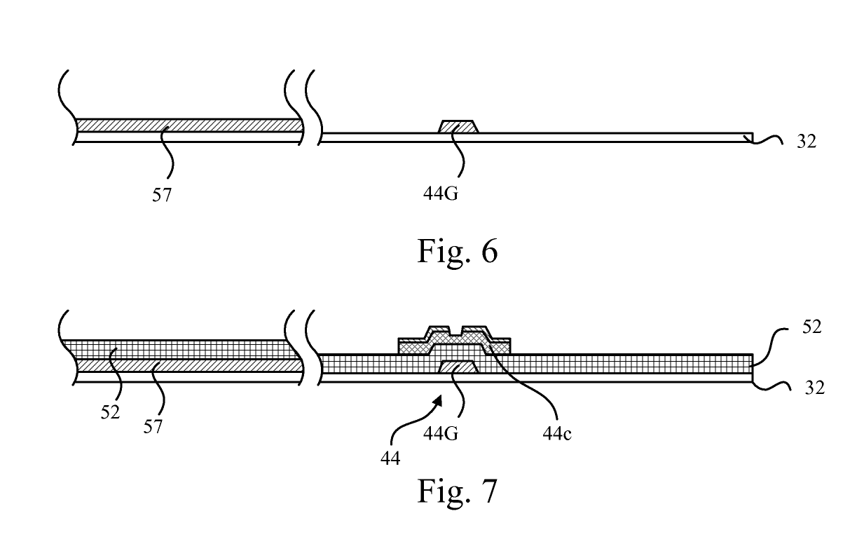

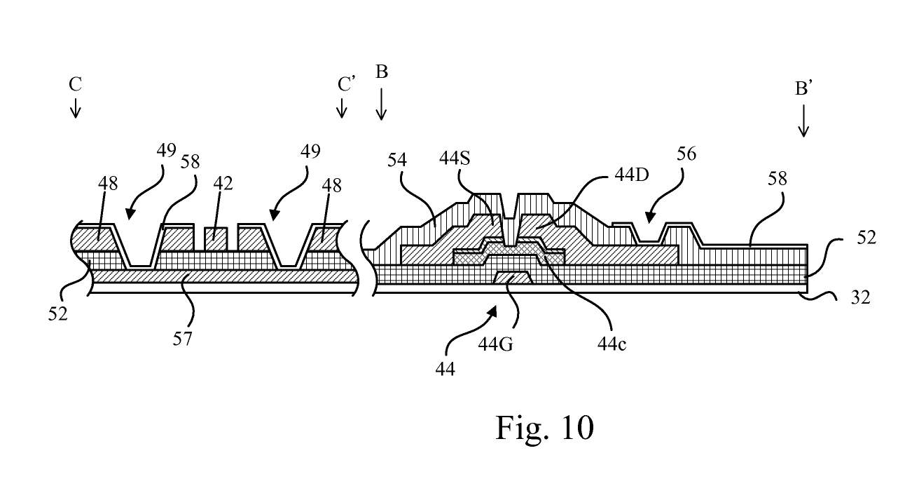

Referring to FIGS. 6 to 10, FIGS. 6 to 10 show schematic diagrams of manufacturing processes of the LCD panel of the present invention. FIG. 10 shows a cross section view of the pixel taken along two lines B-B′ and C-C′ of FIG. 5.

Referring to FIG. 6, a glass substrate 32 is supplied. A metallic thin-film deposition is conducted on the glass substrate 32 to form the first metallic layer (not shown) on the surface of the glass substrate 32. Also, a first photo etching process (PEP) is conducted using a first mask to form the gate 44G of the TFT 44 and the connecting zone 57.

Referring to FIG. 7, the insulating layer 52 made of silicon nitride (SiNx) is deposited and covers the gate 44G and the connecting zone 57. An amorphous Si (a-Si) layer and an N+ a-Si layer at high electron doping concentrations are deposited on the insulating layer 52 successively. A semiconductor layer 44s is formed after a second PEP is conducted using a second mask. The semiconductor layer 44s comprises an a-Si layer 44a and an ohmic contact layer 44b. The a-Si layer 44a serves as a passage of the TFT 44; the ohmic contact layer 44b is used for reducing resistance.

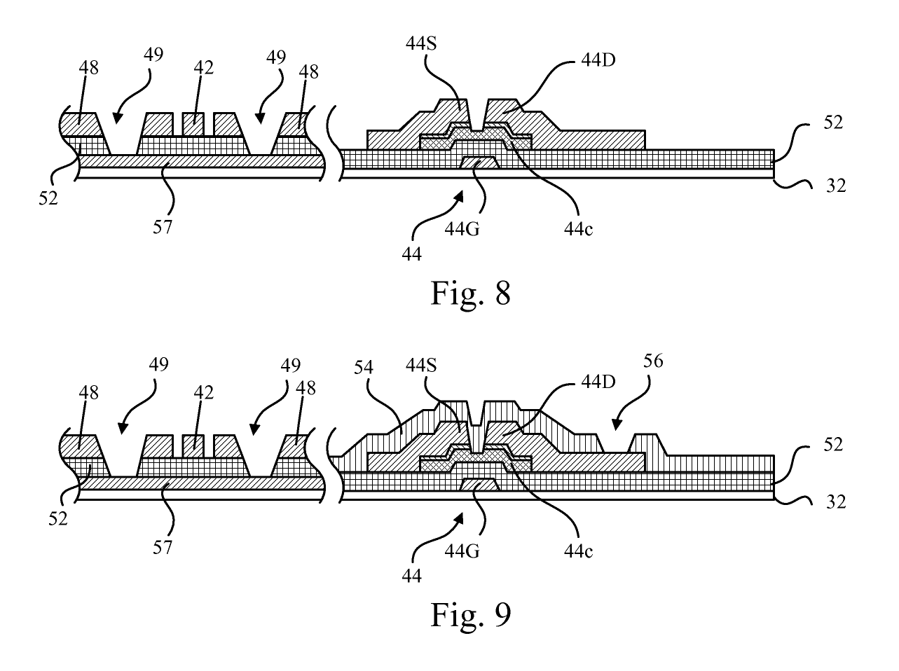

Referring to FIG. 8, the second metallic layer (not shown) is formed on the insulating layer 52 and covers the insulating layer 52 completely. The source 44S and drain 44D of the TFT 44, the common electrode line 48, and the data line 42 are defined after a third PEP is conducted using a third mask. The data line 42 is directly connected to the source 44S. Meanwhile, the via 49 is formed on the insulating layer 52 after the third PEP is conducted.

Referring to FIG. 9, a passivation layer 54 made of SiNx is deposited, covering the source 44S, the drain 44D, and the data line 42. Next, a fourth PEP is conducted using a fourth mask to remove part of the passivation layer 54 on the drain 44D until the surface of the drain 44D is exposed. A hole 56 is formed on the drain 44D.

Referring to FIG. 10, a transparent conducting layer made of ITO is formed on the passivation layer 54. Next, the pixel electrode 58 is formed after the transparent conducting layer is etched using a fifth mask. The pixel electrode 58 is electrically connected to the drain 44D of the TFT 44 via the via 56 formed beforehand. Meanwhile, the pixel electrode 58 is formed on the via 49, causing the common electrode line 48 to be electrically connected to the connecting zone 57.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A liquid crystal display (LCD) panel, comprising a plurality of pixels, a plurality of rows of scan lines parallel to one another and arranged along a first direction, and a plurality of columns of data lines parallel to one another and arranged along a second direction, the second direction being perpendicular to the first direction, the plurality of rows of scan lines formed by a first metallic layer for transmitting scan signals, the plurality of columns of data lines formed by a second metallic layer for transmitting data signals, each of the plurality of pixels comprising a plurality of subpixels, characterized in that: each of the plurality of subpixels comprises:
a pixel electrode, formed by a transparent conducting layer;
an insulating layer disposed between the first and second metallic layers;
a thin-film transistor (TFT), connected to the pixel electrode, the scan line, and the data line; and
a common electrode line, comprising a main branch, a first shielding metallic area, and a second shielding metallic area, the first and second shielding metallic areas being parallel to the plurality of scan lines and being connected to the main branch, and the common electrode line formed by the second metallic layer;
wherein two vias are defined on the insulating layer, and the transparent conducting layer is positioned on the two vias and on the first metallic layer, so that two main branches of common electrode lines corresponding to two subpixels which are on two sides of one of the data lines and are connected to one of the scan lines are electrically connected to each other through the transparent conducting layer and the first metallic layer.

2. The LCD panel of claim 1, characterized in that: each pixel comprises a red subpixel, a green subpixel, and a blue subpixel.

3. The LCD panel of claim 1, characterized in that: the transparent conducting layer is made of indium tin oxide.

4. A liquid crystal display (LCD) panel, comprising a plurality of pixels, a plurality of rows of scan lines parallel to one another and arranged along a first direction, and a plurality of columns of data lines parallel to one another and arranged along a second direction, the second direction being perpendicular to the first direction, the plurality of rows of scan lines formed by a first metallic layer for transmitting scan signals, the plurality of columns of data lines formed by a second metallic layer for transmitting data signals, each of the plurality of pixels comprising a plurality of subpixels, characterized in that: each of the plurality of subpixels comprises:
a pixel electrode, formed by a transparent conducting layer;
a thin-film transistor (TFT), connected to the pixel electrode, the scan line, and the data line; and
a common electrode line, comprising a main branch, a first shielding metallic area, and a second shielding metallic area, the first and second shielding metallic areas being parallel to the plurality of scan lines and being connected to the main branch, and the common electrode line formed by the second metallic layer.

5. The LCD panel of claim 4, characterized in that: the main branch of the common electrode line appears cruciform.

6. The LCD panel of claim 4, characterized in that: the LCD panel further comprises an insulating layer disposed between the first and second metallic layers.

7. The LCD panel of claim 6, characterized in that: two common electrode lines which correspond to two of the plurality of subpixels, are disposed at two sides of one of the data lines, and are connected to one of the scan lines are electrically connected to each other.

8. The LCD panel of claim 7, characterized in that: the LCD panel further comprises two vias penetrating the insulating layer, and the transparent conducting layer is positioned on the two vias and on the first metallic layer, causing the two common electrode lines to be electrically connected to each other through the transparent conducting layer and the first metallic layer.

9. The LCD panel of claim 8, characterized in that: the first shielding metallic area of one of the two common electrode lines is electrically connected to the first shielding metallic area of the other, or the second shielding metallic area of one of the two common electrode lines is electrically connected to the second shielding metallic area of the other through the transparent conducting layer and the first metallic layer.

10. The LCD panel of claim 4, characterized in that: each pixel comprises a red subpixel, a green subpixel, and a blue subpixel.

11. The LCD panel of claim 4, characterized in that: the transparent conducting layer is made of indium tin oxide.

12. A method of manufacturing an LCD panel, comprising:
providing a glass substrate;
forming a first metallic layer on the glass substrate;
etching the first metallic layer for forming a gate of a TFT and a scan line;
forming an insulating layer on a gate of the TFT and on the scan line;
forming a passage of the TFT on the insulating layer; and
forming and etching a second metallic layer for forming a source and a drain of the TFT, a common electrode line, and a data line wherein the common electrode line comprises a main branch, a first shielding metallic area, and a second shielding metallic area, and the first and second shielding metallic areas are parallel to the scan line and are connected to the main branch.

13. The method of manufacturing the LCD panel of claim 12, characterized in that: the method further comprises:
forming a passivation layer on the data line, the common electrode line, and on the source and drain of the TFT;
etching a via on the passivation layer under the common electrode line; and
forming a transparent conducting layer on the via and on the first metallic layer, causing the common electrode line to be electrically connected to the first metallic layer through the transparent conducting layer.

14. The method of manufacturing the LCD panel of claim 12, characterized in that: the method further comprises:
etching the passivation layer on the drain for forming a hole while etching the passivation layer under the common electrode line for forming the via; and
forming the transparent conducting layer on the hole for producing a pixel electrode while forming the transparent conducting layer on the via and on the first metallic layer.
